(19) United States
(12) Patent Application Publication
(10) Pub. No.: US 2016/0172510 A1
(43) Pub. Date: Jun. 16, 2016

(54) PHOTOVOLTAIC MODULE

(71) Applicant: SOLARWORLD INNOVATIONS GMBH, Freiberg (DE)

(72) Inventor: Bernd BITNAR, Bannewitz (DE)

(21) Appl. No.: 14/942,406

(22) Filed: Nov. 16, 2015

(30) Foreign Application Priority Data
Dec. 10, 2014 (DE) 102014118332.0

(51) Int. Cl. H01L 31/0224; H01L 31/05; H01L 31/0216; H01L 31/068

(52) U.S. Cl. CPC H01L 31/022433; H01L 31/0684; H01L 31/0504; H01L 31/02167

(57) ABSTRACT

The invention relates to bifacial solar cells and a photovoltaic module comprising several bifacial solar cells and an electrical connecting structure, through which the solar cells are electrically connected. The solar cells are configured rectangular with an aspect ratio different from one. The solar cells have a first contact grid with first contact elements on a first side and a second contact grid with second contact elements on a second side opposite the first side. The electrical connecting structure has wire guides connected to the first and second contact elements of the solar cells. The invention further relates to a process for manufacturing a photovoltaic module.

The present invention relates to a photovoltaic module comprising several solar cells and an electrical connecting structure, through which the solar cells are electrically connected. The invention relates further to a process for manufacturing a photovoltaic module.

Solar cells are used for converting electromagnetic radiation energy, particularly sunlight into electric energy. The energy conversion is based on that the radiation in a solar cell is subjected to an absorption, whereby positive and negative charge carriers (electron-hole pairs) are generated. The generated free charge carriers are further isolated from each other in order to be carried off towards the isolated contacts.

Conventional solar cells have a square or pseudo-quadratic Silicon substrate, in which two areas are configured with different conductivity or doping. Between both the areas, which are also referred to as base and emitter, there is a p-n junction. This is associated with the presence of an inner electric field, which causes the isolation of the charge carriers generated by radiation.

Solar cells have contact structures on the front side and on the rear side for tapping the charge carriers. Usually, finger-shaped contact elements and stripe-shaped contact elements, also referred to as contact fingers and busbars, are located on the front side and a flat contact element and busbars are configured on the rear side.

A photovoltaic or solar module has several interconnected solar cells. Generally, the solar cells are connected to several strings in series via cell connectors, which for their part are similarly connected in the form of a series connection. Common cell connectors are in the form of strips of copper, which are connected to the front and rear side busbars of the solar cells.

The object of the present invention is to provide an improved photovoltaic module, which is distinguished by a high efficiency.

This object is accomplished by the features of the independent patent claims. Further advantageous embodiments of the invention are claimed in the dependent claims.

According to an aspect of the invention, a photovoltaic module is proposed. The photovoltaic module has several solar cells and an electrical connecting structure, through which the solar cells are electrically connected. The solar cells are configured rectangular with an aspect ratio different from one. The solar cells have a first contact grid with first contact elements on a first side and a second contact grid with second contact elements on one of the second side opposite the first side. The electrical connecting structure has a wire guides connected to the first and second contact elements of the solar cells.

The rectangular design of the solar cells with the aspect ratio different from one refers to the contour of the solar cells present in a top view. The term “rectangular” used in this context includes a pure rectangular shape as well as a shape corresponding to a right angle. A solar cell according to the first variant has a rectangular contour with four corners. A solar cell according to the second variant has a contour, which corresponds to a rectangular basic shape, wherein deviating from the rectangular basic form, at least one corner area is configured chamfered and/or round or rounded.

For the second variant in the following, the expression “pseudo-quadratic” is also used analogous to the term “pseudo-quadratic”, by which solar cells are characterized by a shape corresponding to a square with four chamfered or rounded corner areas. A pseudo-rectangular solar cell has a shape corresponding to a rectangle with at least one chamfered and/or rounded corner area. For example, a pseudo-rectangular solar cell can have two chamfered and/or rounded corner areas.

In the aspect ratio different from one, of the rectangular solar cells involves a length-width ratio. In view of a rectangular solar cell, the aspect ratio refers to the longer and shorter lateral sides of the rectangular solar cell shape. In an pseudo-rectangular solar cell, the aspect ratio refers to the lengths and short lateral sides of the rectangular basic shape, by which the solar cells can take shape or from which the solar cell shape can be derived.

In the photovoltaic module, rectangular solar cells with an aspect ratio different from one are used, instead of conventional quadratic or pseudo-quadratic solar cells. In this way, the photovoltaic module can have a greater number of solar cells in comparison to a module with (pseudo) quadratic cells in the same module or cell surface. Here, the solar cells can be interconnected via the connecting structure of the photovoltaic module, such that the operation of the photovoltaic module can be achieved with lower ohmic resistive losses and a higher efficiency.

Similarly, the advantage is that the solar cells of the photovoltaic module have respective grid-like contact structures in the form of the first or second contact grid on the first and on the second side opposite thereto. This construction enables a two-sided coupling/launching of light radiation in the solar cells, i.e. over the first and second sides of the solar cells, whereby the solar cells have a higher efficiency. Because of this property, the solar cells are referred to as bifacial solar cells.

In a possible mode of operation of the photovoltaic module, the bifacial solar cells with the first or second side can face the light radiation (sunlight), so that the light radiation can be launched into the solar cells over the relevant side. Scattered light from the surroundings can be launched into the solar cells over the other of the two sides.

The configuration with the first and second contact grids enables a minimum shadowing of the first and second side of the solar cells. A minimum shadowing of the solar cells and thereby a higher efficiency further result in that the electrical connecting structure of the photovoltaic module includes wire guides for connecting the solar cells, instead of strip-like cell connectors. Here, the wire guides are connected to the first or the second contact elements of the contact grids of the solar cells configured on both the sides.

In the following, further possible details and embodiments of the photovoltaic module are described in more details.

The first side of the solar cells can involve a front side, and the second side can involve a rear side of the solar cells (or vice-versa). The front side can be any side, which can face the light radiation or sunlight during the operation of the photovoltaic module.

The first and second contact elements, which are respectively provided on the first and second side of the solar cells, can involve separate contact elements. The first and second contact elements can have an elongated shape. Furthermore, the first and second contact elements can be configured respectively extending parallel to each other.

In a further embodiment, the first and second contact elements respectively have several sections, which are configured alternating in the shape of contact lines and contact surfaces. Here, the wire guides of the electrical connecting structure are connected to the contact surfaces of the first and second contact elements. Such a structure of the contact elements with alternating contact lines and contact surfaces, in which the contact lines and contact surfaces can be alternatingly border one another or merge into one another, favours the presence of a minimum shadowing of the first and second side of the solar cells, and enables a reliable contacting of the contact elements via the wire guides. Here, the contact lines can have a relatively smaller width, and the contact surfaces can have a larger width with respect to the width of the contact lines and suitable width for a reliable contacting.

The first and second contact elements of the solar cells can be configured further such that the contact surfaces of different contact elements of an associated contact grid are pooled in rows of contact surfaces disposed adjacent to each other. Here, the contact surface rows, which can extend perpendicular to the respective contact elements, are placed at the same level with the non-continuous segmented busbars, and thus the contact surfaces with busbar-segments. In this configuration, wire guides of the electrically connecting structure can be connected to the rows of the contact surfaces of different contact elements disposed adjacent to each other.

In another embodiment, the contact lines of the first or second contact grid or the first or second contact elements of the solar cells have Aluminum. In this configuration, which can be provided for a rear side of the solar cells, the solar cells can be manufactured cost-effectively. The contact surfaces of the contact elements associated therewith can have a solderable metal such as Silver. A configuration of a solderable metal or Silver can also be provided for the other of the two contact grids of the solar cells, i.e. for the contact lines and contact surfaces of the contact elements of this contact grid.

In another embodiment, at least five wire guides are connected respectively on the first and second contact elements of the solar cells. With reference to the above described configuration of the contact elements with an alternating structure of contact lines and contact surfaces, the contact elements of the solar cells can have at least five contact surfaces respectively corresponding thereto. This embodiment enables a reliable electrical connection of the solar cells with a low electric resistance.

For example, it can be provided that a number of wire guides—in a range of twenty to thirty—are respectively connected to the contact elements of the solar cells. In this context, the contact elements can have a corresponding number of contact surfaces, i.e. likewise in a range of twenty to thirty.

In another embodiment, the wire guides of the electrical connecting structure are respectively connected to the first and second contact elements of the solar cells via a solder joint. In this way, there is a reliable electrical connection of these components.

In another embodiment, the rectangular configured solar cells have an aspect ratio of 2:1. By means of such solar cells, the operation of the photovoltaic module is possible with relatively lower ohmic resistive losses in a suitable layout and electrical connection of the solar cells. Even rectangular, i.e. is rectangular or pseudo-rectangular solar cells can be provided with an aspect ratio of 2:1 by means of severing or halving of square or pseudo-quadratic output solar cells. This procedure represents a method simple and suitable from the manufacturing point of view, for providing solar cells, by means of which the resistive losses can be kept low.

In another embodiment, the solar cells have a substrate of Silicon with a p-doped base and an n-doped emitter. This configuration favours an easy manufacture of the solar cells.

The solar cells can have a substrate of polycrystalline Silicon. It is also possible that the solar cells have a Silicon substrate with a monocrystalline or a substantially monocrystalline structure. Thus, the solar cells can likewise have a high efficiency. Substrates with a predominantly monocrystalline Silicon structure can be obtained similar to polycrystalline Silicon substrates from a Silicon block, which can be manufactured by means of a cost-effective casting process. Monocrystalline Silicon substrates can be obtained from a block or rod of Silicon, which can be manufactured by means of a Czochralski process or a Float-zone process.

The contact grids of the solar cells can be connected to the associated substrate, so that the charge carriers generated during the operation by radiation, can be tapped by means of the contact grids. Here, the further configurations described in the following can be provided for the solar cells.

In addition to the solar cells substrate and the contact grids configured on both the sides of the substrate, the solar cells can have further components. For example, the solar cells can have an anti-reflection coating, which is disposed on one of the first or second side or on a front side of the solar cell. By means of the anti-reflection coating, the radiation reflection and the yield losses associated therewith can be reduced or suppressed. The contact elements of the contact grid provided on this side can extend through the anti-reflection coating to the solar cells substrate and contact the substrate.

Another possible component of the solar cell is a passivation layer with openings on one of the first or second side or on a rear side of the solar cell. At least the contact lines of the contact grid provided on this side can contact the solar cell substrate over the openings of the passivation layer. If the contact lines have Aluminum, there can be a local rear side field (BSF or Back Surface Field) respectively in the region of the contact points. Through the passivation layer and if necessary, the locally present rear side field, it is possible to suppress a recombination of charge carriers generated and yield losses associated therewith. The passivation layer can also cause suppression of the radiation reflection, comparable to the front side anti-reflection coating.

In another embodiment, the solar cells are connected via the electrical connecting structure such that the photovoltaic module has several strings of solar cells connected in series. In the strings, the solar cells are disposed with their long sides facing one another. Furthermore, several strings are connected in parallel.

The rectangular configuration of the solar cells with the aspect ratio different from one, instead of the conventional square shape or pseud-quadratic shape make the configuration of strings possible, which includes a larger number of solar cells than a comparable string (pseudo)quadratic cells. During operation, such a string of rectangular solar cells can provide a higher electric voltage. However, the electric current flowing in the string is smaller than in a string of (pseudo)quadratic cells, whereby there are lower ohmic resistive losses.

In the abovementioned embodiment of the photovoltaic module, all strings can have one such property. The parallel connection of several strings offers the possibility of counteracting an excessive increase of the voltage due to large number of solar cells per string. It is possible that the photovoltaic module has several layouts of parallel connected solar cell strings, wherein such string layouts, for their part, can be connected in series.

By using solar cells or half-cells with an aspect ratio of 2:1, for example, strings of solar cells can be realized, which have doubled number of solar cells as against the strings of conventional (pseudo)quadratic cells. In comparison to the strings of (pseudo)quadratic cells, such strings can provide doubled voltage, and can pass merely half the electric current. Here, a configuration of the photovoltaic module can be considered, in which (respectively) two strings are connected in parallel. Such a string layout or such a double-string can generate the same voltage as a string built of the same number of (pseudo)quadratic cells.

In another embodiment, adjacently disposed solar cells of parallel connected strings are additionally connected in parallel one below the other. This configuration enables the flow of transient currents between the parallel connected solar cells of the different strings, whereby for example, power losses resulting from partial shadowing can be reduced. This includes not only direct shadows of the solar cells themselves, but also for example, shadowing effects in the surrounding of the photovoltaic module. This results in a corresponding reduction of scattered light usable by means of bifacial solar cells.

The electrical connecting structure of the photovoltaic module can include further components besides the wire guides. For example, the connecting structure can have cross connectors, which are disposed at the border of the photovoltaic module or at the border of the solar cells. By means of the cross connectors, the abovementioned parallel connection of several strings can be made into a string layout and the series connection of a string layouts. The cross connectors can be connected to the border side solar cells of the photovoltaic module via wire guides. Even here, a solder joint can be respective provided between the wire guides and the cross connectors.

Furthermore, the electrical connecting structure can have intermediate connectors, which are disposed between the solar cells, and which can be connected to wire guides. A series connection of the solar cells of a string can be realized as mentioned in the following. Here, respectively two adjacent solar cells of the strings can be connected in series via several first wire guides, an intermediate connector located between the two solar cells and several second wire guides. The first wire guides can be connected to the first contact elements of one of the two solar cells and to the intermediate connector, for example, respectively via a solder joint. The second wire guides can be connected to the second contact elements of the other of the two solar cells and to the intermediate connector, for example, respectively via a solder joint. The intermediate connector can be oriented perpendicular to the first and second wire guides. Furthermore, the intermediate connector can be realized, if necessary, in the form of a wire guide.

The abovementioned intermediate connector can furthermore be used for realizing the above described additional parallel connection of adjacently disposed solar cells of different and parallel connected strings. Here, the intermediate connectors extend between the solar cells of the different strings and are connected to the wire guides of the different strings.

Alternatively, a configuration of the electrical connecting structure of the photovoltaic module without intermediate connector is possible. For this, two adjacent solar cells in a string can respectively be connected in series via several wire guides, wherein the wire guides are connected to the first contact elements of one of the two solar cells and to the second contact elements of the other of the two solar cells.

The electrical connecting structure of the photovoltaic module can further have at least one bridge structure of a bridge connector and one or more bypass-diodes. The bridge structure can be configured such that the current flowing in the photovoltaic module can be bypassed to solar cells or to a string layout. This can occur in presence of a malfunction, such as a partial shadowing, in order to prevent a negative impairment of the current flow in the photovoltaic module. For example, the bridge connector can be connected to a cross connector disposed on a border side of the photovoltaic module, and can be connected to a cross connector disposed on an opposite border side via a bypass-diode. Furthermore, the bridge connector can also be connected to the relevant border side with two cross connectors, wherein the connection is realized respectively via a dedicated bypass-diode.

In addition, the photovoltaic module can have further components. For example, the solar cells including components of the electrical connecting structure can be disposed in a transparent embedded layer between a first and second translucent cover. It is possible that both the covers are glass discs. Alternatively, at least one of the covers can be a translucent film. Furthermore, the photovoltaic module can have a frame.

According to another aspect of the invention, a method is proposed for manufacturing a photovoltaic module. The photovoltaic module has the above described construction or a construction corresponding to one or more of the above described embodiments. The method includes providing the solar cells. The solar cells are configured rectangular with an aspect ratio different from one. The solar cells have a first contact grid with first contact elements on a first side and a second contact grid with second contact elements on one second side opposite to the first side. Further, there is provided making an electrical connecting structure, through which the solar cells are electrically connected. The electrical connecting structure has wire guides, which are connected to the first and second contact elements of the solar cells. Furthermore, the method includes arranging the solar cells electrically connected via the electrical connecting structure, in an embedded layer between a first and second translucent cover.

The photovoltaic module manufactured according to the method can be distinguished by a higher efficiency. The rectangular, i.e. according to the above definition, rectangular or pseudo-rectangular geometry or contour of the solar cells with the aspect ratio different from one, enables the interconnection of the solar cells, in which low resistive losses occur. Based on the configuration of the solar cells with double-sided contact grids and the use of wire guides, a double-sided radiation launching into the solar cells is possible, and a lower shadowing of the solar cells can be achieved.

It should be noted that above embodiments mentioned with reference to the photovoltaic module and details can be used accordingly during the manufacturing process.

In this sense, it is provided according to one embodiment that the wire guides are connected by soldering to the first and second contact elements of the solar cells. Even other components, by which the photovoltaic module or the electrical connecting structure can be built, can be interconnected by soldering. For example, this includes a connection of wire guides and cross connectors disposed at the border of the photovoltaic module and a connection of wire guides and intermediate connectors (if intermediate connectors are used) disposed between the solar cells.

In this context further, it can be considered initially to arrange the components of the electrical connecting structure along with the solar cells of the photovoltaic module. Subsequently, a soldering process can be carried out, in which, the corresponding solder joints can be configured successively or simultaneously. In view of the soldering process, the wire guides can be provided with a coating of a solder. Subsequent to the soldering process, surplus electric connection or short circuit connections can be isolated. For this purpose, wire guides can be severed at corresponding points, for example, by using a Laser or mechanically by means of a slitting device. Such a procedure enables a simple manufacture of the photovoltaic module.

In another embodiment, providing the solar cells includes providing solar cell output and a division of the output solar cell. The solar cell outputs can have, for example, a square shape, and for example, can be divided into rectangular solar cells with an aspect ratio of 2:1. Furthermore, the output solar cell can have, for example, a pseudo-quadratic shape with four chamfered and/or rounded corner areas, and for example, can be divided into pseudo-rectangular solar cells with two chamfered and/or rounded corner areas and an aspect ratio of 2:1. These configurations of the method are suitable from the manufacturing point of view and do not require any or substantially any adaptation of the solar cell manufacture.

The above explained features and/or the advantageous configurations and improvements of the invention claimed in the subordinate claims can be used—except for example in cases of clear dependencies or incompatible alternatives —individually or also in any combination with each other.

The invention will be explained in more details in the following by means of the schematic figures. They show:

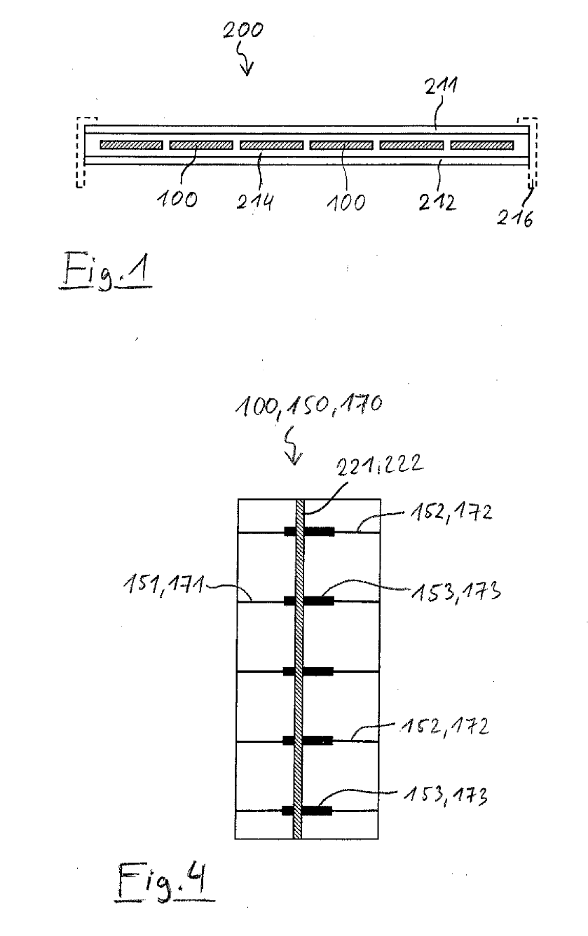

FIG. 1 shows a photovoltaic module in a lateral sectional representation;

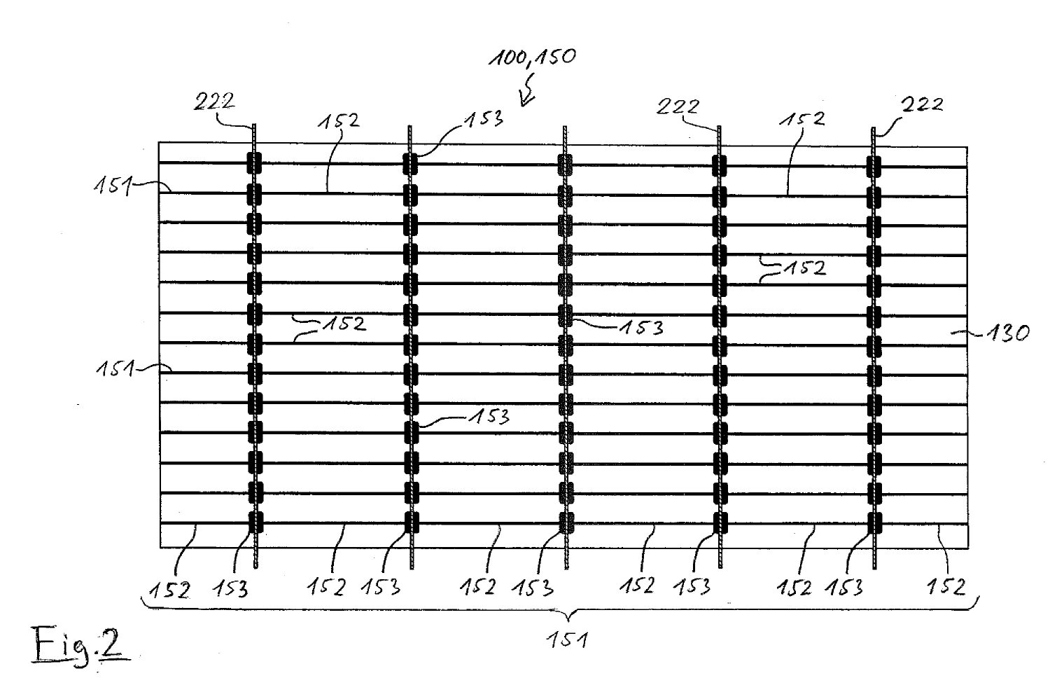

FIG. 2 shows the front side of a rectangular solar cell;

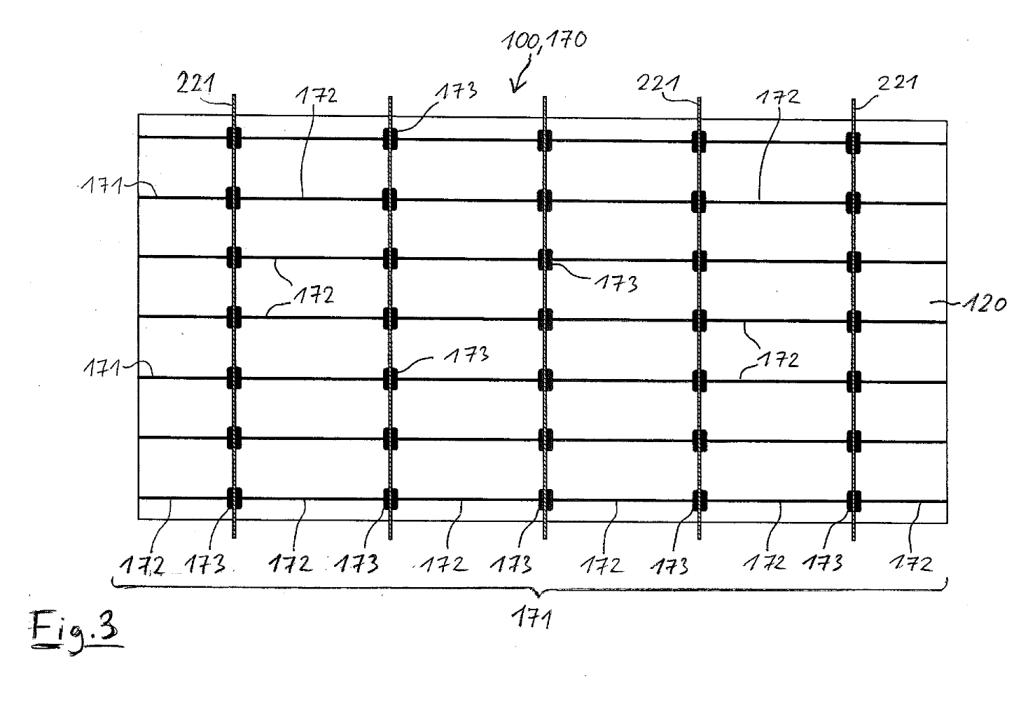

FIG. 3 shows the rear side of a rectangular solar cell;

FIG. 4 shows a sectional representation of a solar cell in the region of contact surfaces of the solar cell;

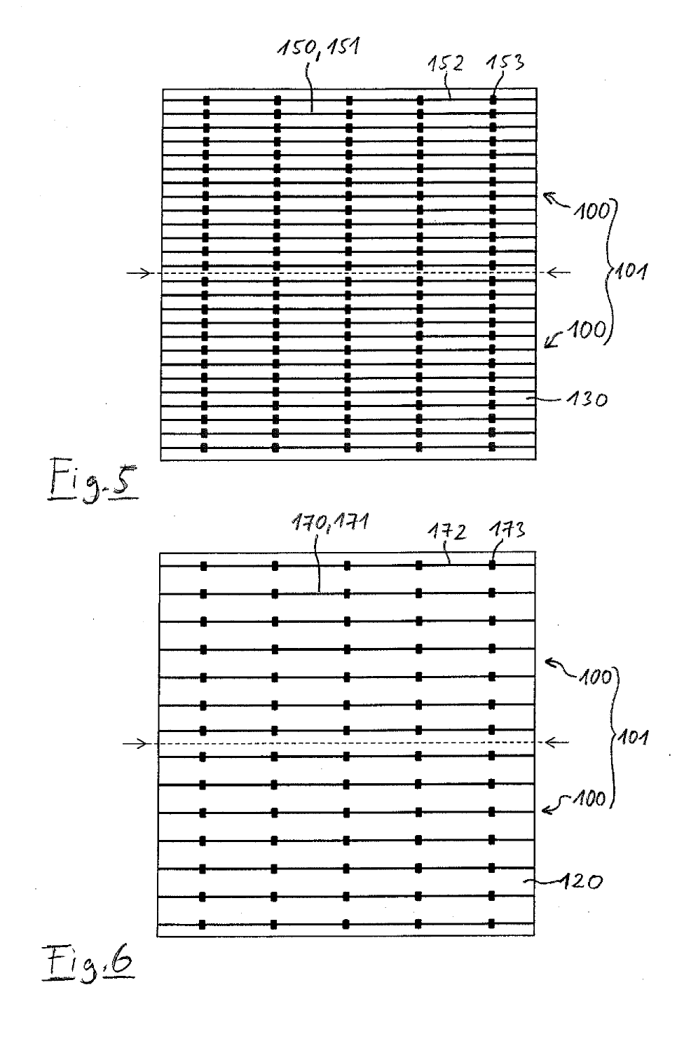

FIG. 5 shows the front side of a square output solar cell;

FIG. 6 shows the rear side of a square output solar cell;

FIGS. 7 to 10 show a process sequence for manufacturing a solar cell;

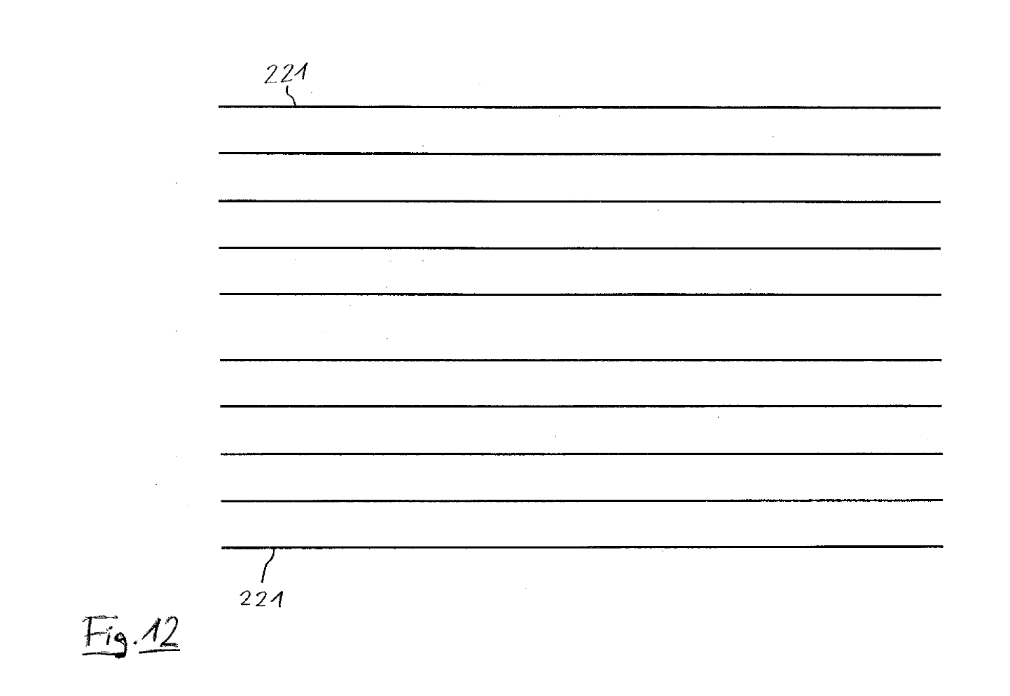

FIG. 11 shows the interconnection of solar cells;

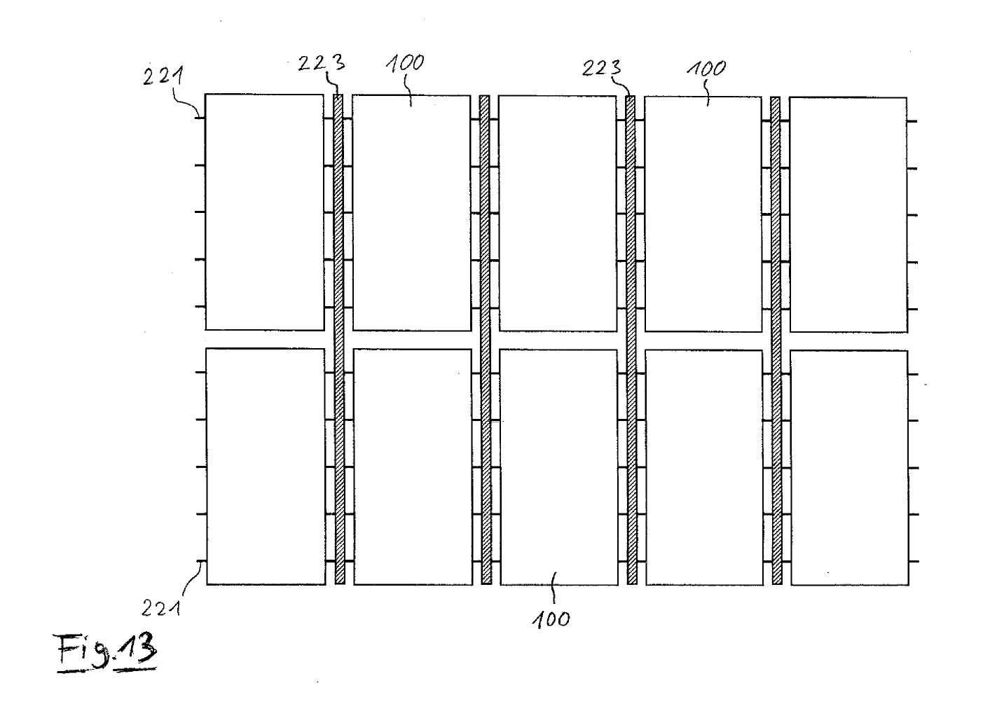

FIGS. 12 to 15 show a process sequence for electrically connecting solar cells by means of wire guides;

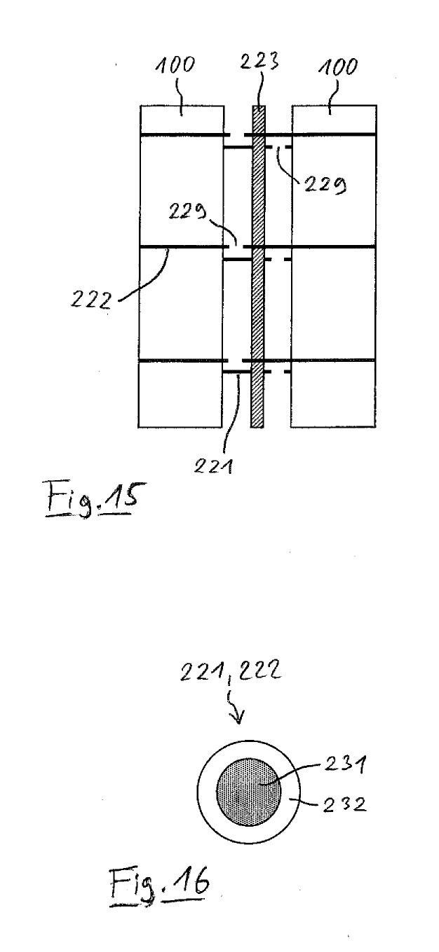

FIG. 16 shows a sectional representation of a wire guide;

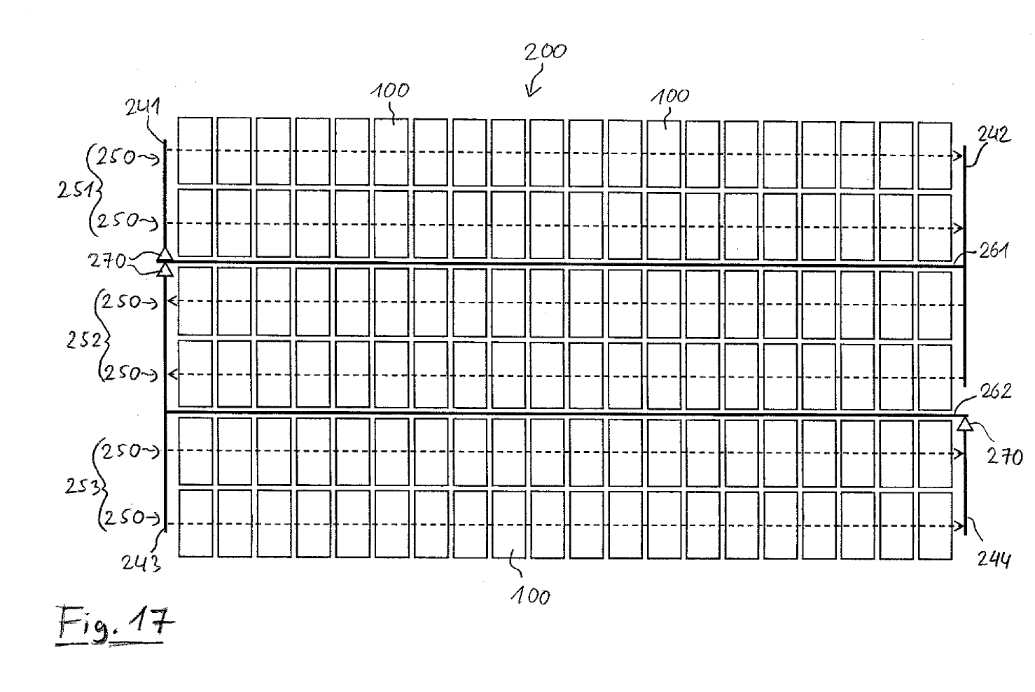

FIG. 17 shows another interconnection of solar cells;

FIGS. 18 to 20 show another process sequence for electrically connecting solar cells by means of wire guides;

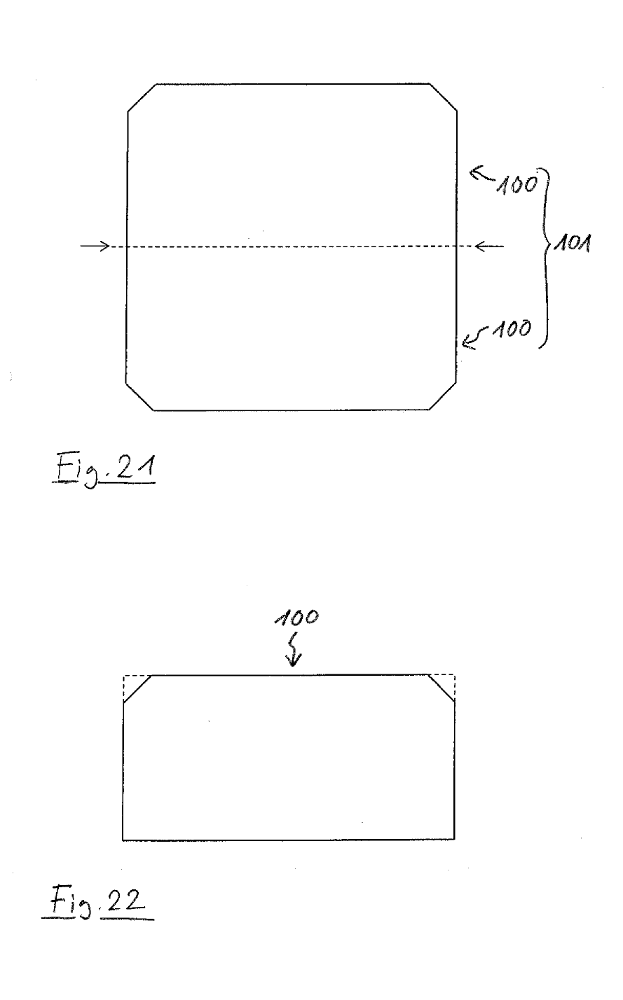

FIG. 21 shows the contour of a pseudo-quadratic output solar cell; and

FIG. 22 shows the contour of a pseudo-rectangular solar cell.

The possible configurations of a photovoltaic module 200 are described by means of the following schematic figures. The photovoltaic module 200 is distinguished by a high efficiency and a higher capability of performance. Individual features and components of the photovoltaic module 200 are additionally explained in more details by means of the manufacture of the photovoltaic module 200. It should be noted in this context that the photovoltaic module 200 or components of the same, such as solar cells 100 can be produced with further components and structures, in addition to shown and described components. It should be noted further that the figures are only of schematic nature and not to scale. In this sense, components and structures shown in the figures can be represented excessively large or small for better understanding.

FIG. 1 shows the schematic lateral sectional representation of a photovoltaic module 200. The photovoltaic module 200, which can also be referred to as solar module 200, has several electrically interconnected solar cells 100. Here, this involves bifacial and thus, solar cells 100 having a high efficiency, in which the coupling/launching of light radiation for electrical power generation can take place over the front side as well as over the rear side of the solar cells 100 placed opposite thereto. In view of FIG. 1, the front side is the cell side of the solar cells 100 oriented upwards, and the rear side is the cell side oriented downwards.

For enabling the double-sided launching of radiation, the solar cells 100 have a contact grid 150, 170 for electrical contacting (c.f. FIGS. 2, 3) on the front side as well as on the rear side. On this and other features, such as the configuration of the solar cells 100 with a rectangular lateral contour having an aspect ratio of 2:1 will be detailed further below in the following.

Furthermore, the photovoltaic module 200 has, as shown in FIG. 1, a front side cover 211 and a rear side cover 212. The solar cells 100, which are disposed in a plane, are located between the two covers 211, 212. Here, the solar cells 100 are embedded, similar to a transparent embedded layer 214, disposed between the covers 211, 212. The embedded layer 214 can be configured, for example, from ethylene vinyl acetate (EVA) or Silicon.

In view of the configuration of the solar cells 100 as bifacial solar cells 100 for front and rear side light collection, both the covers 211, 212 are configured transparent or translucent. For example, both the covers 211, 212 can be realized in the form of glass covers. In an alternative configuration, the front side cover 211 can be a glass cover, and the rear side cover 212 can be a transparent film.

In addition, the photovoltaic module 200 can have a frame 216 at the border, surrounding the covers 211, 212 and the embedded layer 214, as indicated in FIG. 1 by means of dashed lines. Similarly as indicated, the frame 216 can have, for example, an L-shaped profile in the cross-section. The frame 216 can impart a higher stability to the photovoltaic module 200. In a configuration of both the covers 211, 212 in the form of glass discs, the use of frame 216 can be omitted.

During the operation of the photovoltaic module 200, the front side cover 211 and thus, the front sides of the solar cells 100 can face the light radiation (Sunlight). In this way, the light radiation can penetrate the cover 211 and launch via the front side of the solar cells 100 into the solar cells 100. The rear side cover 212 can be penetrated by the scattered light of the surroundings of the photovoltaic module, which can be launched via the rear side of the solar cells 100 into the solar cells 100. A portion of the radiation can be absorbed by the solar cells 100 and converted into electrical energy.

The solar cells 100 are provided for manufacturing the photovoltaic module 200. Furthermore, an electrical connecting structure is configured, wherein the solar cells 100 are disposed from each other according to a predefined interconnection pattern and electrically interconnected. Here, inter alia, wire guides 221, 222 are used for cell connection. Details for solar cells production and for interconnecting the solar cells 100 are described further below in more details. The interconnected solar cells 100, including components of the electrical connecting structure, are further embedded in the transparent embedded layer 214 between both the covers 211, 212. For this purpose, a lamination process is carried out, in which the embedding material 214, for example provided in the form of one or more films, is fused. The bond produced by the lamination can subsequently be provided with the encompassing frame 216. Further, the assembly of one or more junction boxes, not Shown, on the photovoltaic module 200 is possible.

The solar cells 100 of the photovoltaic module 200 are configured rectangular with an aspect ratio (length-width ratio) of 2:1 and have a contact grid 150 on the front side and a contact grid 170 on the rear side. For illustrating these features, FIGS. 2, 3 show a possible configuration of a corresponding solar cell 100, wherein a front side is shown in FIG. 2 and a rear side of the solar cell 100 is shown in FIG. 3. The rectangular view enables such a layout or interconnection of the solar cells 100 that the photovoltaic module 200 can be operated with lower ohmic resistive losses. The double-sided contact grids 150, 170 enable, as specified above, a two-sided radiation launching, whereby the solar cells 100 have a higher efficiency. The contact grids 150, 170 are configured further, such that the contact grids 150, 170 can be reliably contacted by means of wire guides 221, 222 and there is a lower shadowing of the front and rear side of the solar cells 100.

The solar cell 100 illustrated in the FIGS. 2 and 3 has a rectangular contour and has sides with different lengths, i.e. two long sides and two short sides. Here, the aspect ratio of 2:1 refers to the long and short sides. Accordingly, the long sides of the solar cell 100 are double the length of the short sides.

Instead of using the solar cells 100 with the pure rectangular shape shown in the FIGS. 2, 3 and also in other Figures, the photovoltaic module 200 can also be realized with solar cells 100 with a pseudo-rectangular shape. Here, the contour of a solar cell 100 corresponds to a rectangular basic shape and is configured with at least one corner area chamfered and/or rounded (cf. FIG. 22), deviating from the rectangular basic shape. In a pseudo-rectangular solar cell 100, the aspect ratio of 2:1 refers to the long and short sides of the rectangular basic shape. It should be noted that aspects and details, such as the configuration of the contact grids 150, 170, the contacting of the contact grids 150, 170 by means of wire guides 221, 222 etc., which is explained in the following by means of the rectangular solar cell 100 shown in the Figures, can also be used for a pseudo-rectangular solar cell 100. In other words, a pseudo-rectangular solar cell 100 can have the same construction as the rectangular solar cell 100, except for the lateral contour.

The contact grid 150, including an anti-reflection coating 130 (also cf. FIG. 10) is located on the front side of the solar cell 100 shown in FIG. 2. The contact grid 150 has several separate and spaced apart contact elements 151 disposed along length. The contact elements 151, which can be configured from a solderable metal like Silver, extend mutually parallel and parallel to the long sides of the solar cell 100. In the representation of FIG. 2, the contact elements 151 extend in horizontal direction. Each contact element 151 has an alternating structure with adjoining or mutually merging sections in the form of contact lines 152 and contact surfaces 153. The contact lines 152 can also be referred to as contact fingers, and the contact surfaces 153 as solder pads. The contact surfaces 153 used for contacting, as represented in FIG. 2, can also be configured rectangular. The contact lines 152 have a less or (substantially) lesser width as compared to the contact surfaces 153.

The contact grid 150 is configured such that the contact surfaces 153 of different contact elements 151 are pooled in parallel rows of adjacently disposed contact surfaces 153. The contact surface rows extending perpendicular to the contact elements 151 (according to FIG. 2 in vertical direction), can be placed at the same level with segmented busbars.

In the configuration shown in FIG. 2, the contact elements 151 have five contact surfaces 153 respectively. Accordingly, there are five contact surface rows. The configurations with a greater number of contact surfaces 153 per contact element 151 and so corresponding number of contact surface rows, for example, with a number in the range of twenty to thirty, not represented, are also possible.

In FIG. 2 additionally, wire guides 222 of an electrical connecting structure of the photovoltaic module 200 are indicated, which are provided for contacting the contact surfaces 153 of the contact grid 150. The wire guides 222 are connected to the rows of adjacently disposed contact surfaces 153 of the different contact elements 151, whereby the wire guides 222 extend perpendicular to the contact elements 151. For contacting the contact grid 150, a number of wire guides 222 corresponding to the number of the contact surface rows is used, i.e. five in the configuration of FIG. 2.

The contact grid 170, including a passivation layer 120 (also cf. FIG. 10) is located on the rear side of the solar cell 100 shown in FIG. 3. The contact grid 170 has a contact layout corresponding to the front side contact grid 150, and has several separate and spaced apart contact elements 171 disposed along the length. The contact elements 171 extend mutually parallel and parallel to the long sides of the solar cell 100 (according to FIG. 3 in horizontal direction). Corresponding to the front side contact elements 151, each rear side contact element 171 has an alternating structure with adjoining or mutually merging sections in the form of contact lines 172 and contact surfaces 173 (solder pads). The contact surfaces 173 used for contacting can be configured rectangular. The contact fingers or contact lines 172 have a less or (substantially) lesser width than the contact surfaces 173.

The contact grid 170 is likewise configured such that the contact surfaces 173 of different contact elements 171 are grouped in parallel rows of contact surfaces 173 adjacently disposed. The contact surface rows, which extend (according to FIG. 3 in vertical direction) perpendicular to the contact elements 171, can be in a plane with segmented busbars.

The contact elements 171 of the contact grid 170 of FIG. 3 have five respective contact surfaces 173 corresponding to the contact grid 150 of FIG. 2, so that there are again five contact surface rows. The configurations not represented here are also possible, with a greater number of contact surfaces 173 per contact element 171 and so, a corresponding number of contact surface rows, for example with a number in the range of twenty to thirty.

The contact surfaces 173 of a solderable metal or Silver, and the contact lines 172 of the cost-effective metal Aluminum can be configured in the contact grid 170. Here, the rear side contact lines 172 have a greater width than the front side contact lines 152 (cf. FIG. 10) due to manufacturing tolerances. Therefore, it can be considered to configure the rear side contact grid 170 with a lesser number of contact elements 171 as against the front side contact grid 150, as it is also illustrated in the FIGS. 2, 3.

In FIG. 3 additionally, wire guides 221 of an electrical connecting structure of the photovoltaic module 200 are shown, which are provided for contacting the contact surfaces 173 of the contact grid 170. The wire guides 221 are connected to the rows of adjacently disposed contact surfaces 173 of the different contact elements 171, whereby the wire guide 221 extends perpendicular to the contact elements 171. Here, a number of wire guides 221 corresponding to the number of contact surface rows is used, i.e. five in the configuration of FIG. 3.

As it will be described further below in more details, the connection of the wire guides 221, 222 to the contact surfaces 153, 173 of the contact grids 150, 170 of the individual solar cells 100 of the photovoltaic module 200 is made by means of soldering. In this way, a reliable electric connection can be realized. In addition, the use of the wire guides 221, 222 leads to that a minimal front and rear side shadowing of the solar cells 100 is further favoured.

FIG. 4 partially shows a configuration differing from the FIGS. 2, 3, which can be provided for the front and/or rear side contact grids 150, 170 of the solar cells 100 of the photovoltaic module 200. Here, the contact surfaces 153, 173 of the contact elements 151, 171 have a strip-shaped rectangular geometry, and related length measurement of the contact surfaces 153, 173 in the direction of extension of the contact elements 151, 171 (horizontal direction in FIG. 4) is greater than in the configuration of the FIGS. 2, 3. In this way, a larger contacting area is available for connecting the wire guides 221, 222 to the contact surface rows, as also indicated in FIG. 4 by means of the wire guides 221, 222 disposed eccentrically on the contact surfaces 153, 173. However, the width measurement of the contact surfaces 153, 173 of FIG. 4 (perpendicular to the direction of extension of the contact elements 151, 171) is substantially smaller than the length measurement or smaller than in the configuration shown in the FIGS. 2, 3.

Further details for a possible construction of the solar cells 100 of the photovoltaic module 200 will be described in more details in the following by means of a process sequence, according to which the manufacture of the solar cells 100 can be done. Here, the output solar cells 101 are produced, which are respectively divided into two half solar cells 100 with the aspect ratio of 2:1. This is a simple and preferred method from manufacturing point of view in order to provide the solar cells 100.

For producing solar cells 100 with the rectangular contour illustrated in the FIGS. 2, 3, output solar cells 101 with a square shape are produced accordingly. For illustrating this procedure, a front side in FIG. 5 and a rear side of such a square output solar cell 101 is represented in FIG. 6. A division of the output solar cell 101 in two half cells 100 is indicated by means of arrows and a dashed line. The output solar cell 101 has the above mentioned contact grids 150 and 170 on the front and rear side, which include the doubled number of contact elements 151, 171 in view of the two half cells 100 formed by the dividing step. The structure of the contact grids 150, 170 shown in the FIGS. 5, 6 corresponds to any of the FIGS. 2, 3. A configuration corresponding to FIG. 4 is also possible.

The division is done as shown in the FIGS. 5, 6, in the middle of the output solar cell 101 between two contact elements 151 or 171. In this context, if necessary, a configuration not shown can be considered, in which deviating from the FIGS. 5, 6, the contact elements 151 or 171 opposite the dividing region have greater distance from each other.

For producing solar cells 100 with a pseudo-rectangular contour, output solar cells 101 with a pseudo-quadratic shape can be made and divided accordingly. This will be explained further below in more details with reference to the FIGS. 21, 22.

For producing quadratic or pseudo-quadratic output solar cells 101, the process sequence described in the following and represented in the FIGS. 7 to 10 can be used. The production of an output solar cell 101 is shown here by means of partial lateral sectional representations.

In the production process, a substrate 110 (Wafer) of Silicon shown in FIG. 7 is provided. The substrate 110 is p-type, which can be realized, for example, with a doping of Boron. Thereby, providing the substrate 110 can take place, in which a correspondingly doped block of Silicon is made and split by sawing. Here, several substrates 110 can be obtained.

It is possible that the substrate 110 is provided with a polycrystalline, or alternatively with a substantially monocrystalline crystal structure. In the latter variant, higher solar cell efficiency can be achieved. For this purpose, the associated Silicon block can be made by means of a cost-effective casting process, which can be take place in view of producing a substantially monocrystalline crystal structure by additional use of one or more monocrystalline nucleus.

It is also possible, to provide the substrate 110 with a monocrystalline crystal structure, whereby higher or still higher solar cell efficiency can be achieved. For this purpose, the associated Silicon block can be produced by means of a Czochralski process (CZ-process) or a Float-zone process (FZ-process). The Silicon block made in this way can have the design of a circular cylindrical rod.

After providing the p-doped Silicon substrate 110, an etching process is carried out for removing the saw damages. An alkaline etching solution, such as KOH or NaOH is employed for this purpose.

Subsequently, a passivation layer 120 is configured on a rear side surface of the Silicon substrate 110, as shown in FIG. 7. The rear side passivation layer 120 is used for suppressing the recombination of charge carriers generated in the substrate 110 by radiation absorption during the solar cells operation. Furthermore, the passivation layer 120 can act as anti-reflection coating for suppressing the radiation reflection on the rear side. The passivation layer 120 can include a layer stack of several layers, for example of a SiO2 and a Si3N4 layer or of Al2O3 and a Si3N4 layer. A single layer configuration, for example, of Si3N4 is also possible. Such materials can respectively be deposited by a CVD process (chemical gas phase deposition or Chemical Vapour Deposition). In a (partial) layer of SiO2, a thermal oxidation of the rear side substrate surface is also possible.

Then, a front side surface of the substrate 110 is provided with a surface texture not shown. The purpose of this is to favour a front side radiation launching. For this purpose, another alkaline etching process is carried out, for example, with KOH.

After producing the texture, the p-type substrate 110 is subjected to a diffusion process, so that a front side substrate area 112 is provided with an n-doping. Thus, the substrate 110 has two areas 111, 112 with different doping and then a p-n junction, as shown in FIG. 7. This is associated with the presence of an inner electric field, which is used in the solar cells operation for isolation of the charge carriers generated. The differently doped areas are referred to as base 111 and emitter 112. In the present case, the Silicon substrate 110 is thus configured with a p-doped base 111 and an n-doped emitter 112.

The manufacture of the n-type emitter 112 can include infusion (or diffusion) of Phosphorous into the front side substrate surface. This can be realized by the processing of the substrate 110 in an oven with a phosphorous containing atmosphere. Within the scope of this process, a coating of the phosphorous silicate glass (PSG) can be formed on the front side substrate surface, not represented.

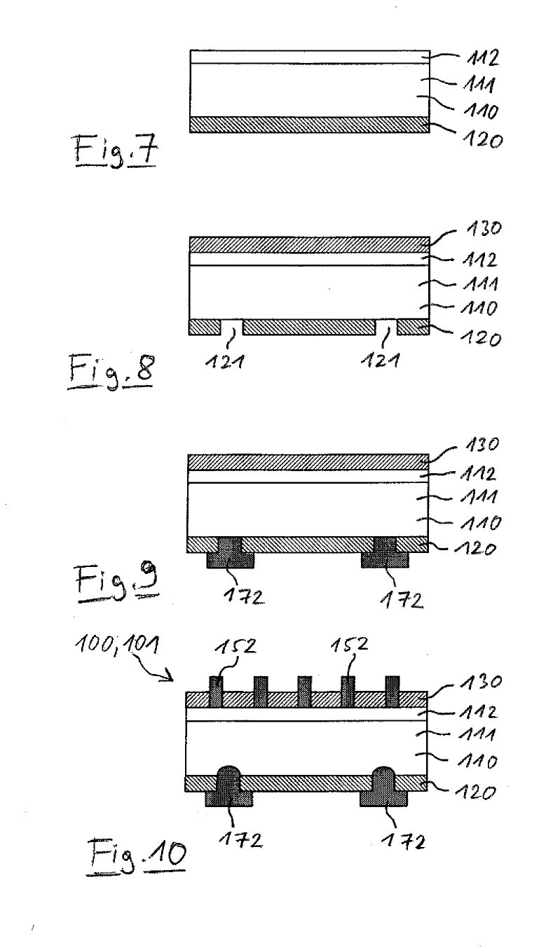

After making the emitter, as shown in FIG. 8, openings 121 are configured in the rear side passivation layer 120, so that the rear side surface of the substrate 110 is locally released at these points. For example, this process carried out by means of a Laser, is done in view of the subsequent making of the rear side contact grid 170. The Laser trenches or openings 121 are configured such that at least the contact lines 172 of the contact grid 170 can contact the substrate 110 on the rear side. It is also possible to make a rear side contacting of the substrate 110 by the contact surfaces 173 of the contact grids 170. According to the configuration, the openings 121 are configured in the form of line segments or points (adapted to the contact lines 172), or in the form of continuous line structures.

Subsequently, another etching process is carried out in order to remove the front side PSG glass formed during making of the emitter.

Then, an anti-reflection coating 130 is configured on the front side surface of the substrate 110, as represented in FIG. 8. The front side anti-reflection coating 130 is used for suppressing the radiation reflection on the front side during the solar cell operation. The anti-reflection coating 130 can be configured, for example, of Si3N4 and deposited by the CVD process.

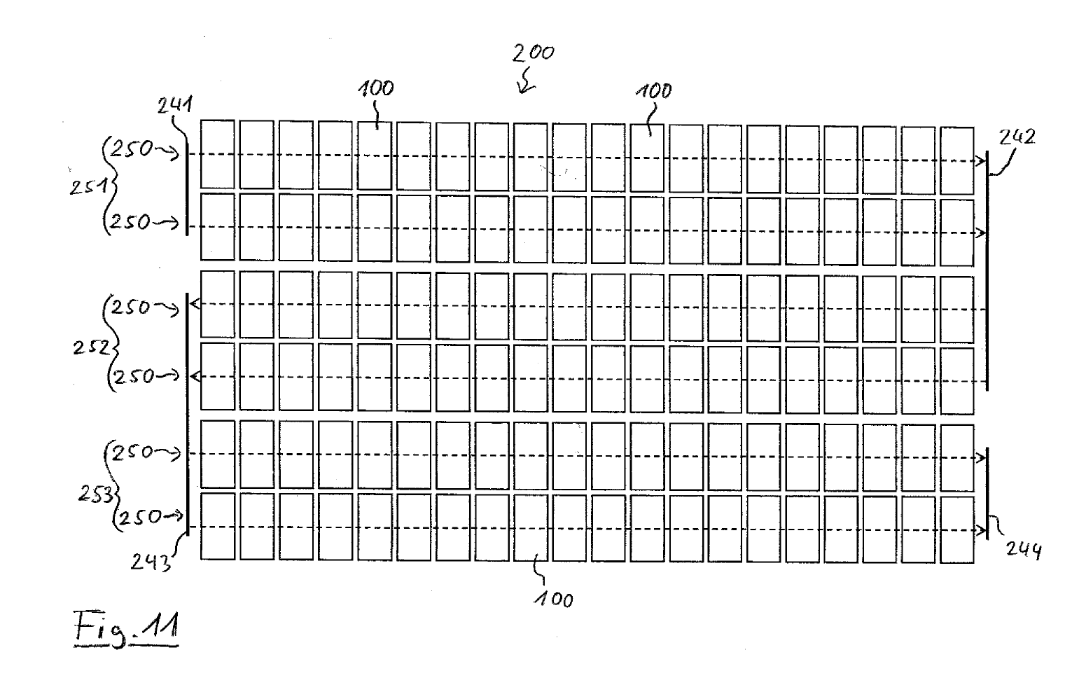

Subsequently, the double-sided contact grids 150, 170 are made with the contact elements 151, 171. For this purpose, in the region of the rear side of the substrate 110 provided with the passivation layer 120 in successive printing processes, for example, screen printing processes, a Silver (Ag) containing paste in the form of the contact surfaces 173 and then an Aluminum (Al) containing paste in the form of the contact lines 172 is applied (cf. FIG. 6; will proceed analogously while making a pseudo-quadratic output solar cell 101). The printed contact lines 172 can slightly overlap the printed contact surfaces 173 on the border. In the sectional representation of FIG. 9, only contact lines 172 are shown.

The contact lines 172 are printed in the region of the openings 121 of the passivation layer 120 and so, printed reaching the substrate 110. As shown in FIG. 9, the printed contact lines 172 cover the passivation layer 120 even beyond the openings 121 or laterally therefrom.

If the openings 121 of the passivation layer 120 are configured in the form of continuous lines, then such a configuration also reaches the printed contact surfaces 173. With openings 121 in the form of line segments or points, the printed contact surfaces 173 can be located only on the passivation layer 120 and are not contiguous to the substrate 110.

In another or subsequent printing process, for example a screen printing process, in the region of the front side of the substrate 110 or on the anti-reflection coating 130 configured in this region, another Silver (Ag) containing paste is applied in the form of the front side contact grid 150 (cf. FIG. 5; will proceed analogously while making a pseudo-quadratic output solar cell 101). This paste has corrosive additives.

Then, a high temperature process referred to as firing is carried out, whereby the contact grids 150, 170 present in the past-like form are solidified and electrically connected to the substrate 110. The corrosive additives in the metal paste of the front side contact grid 150 in this process cause a complete etching of the anti-reflection coating 130, whereby the contact elements 151 of the contact grid 150 are attached through the substrate 110 by the anti-reflection coating 130. In the sectional representation of FIG. 10, this is shown only for the contact lines 152.

Even the rear side contact grid 170 or at least the contact lines 172 are attached to the substrate 110 in the firing step in the region of the openings 121 of the passivation layer 120. Here, as is indicated in FIG. 10, material of the contact lines 172 (Aluminium) can infuse/diffuse into the substrate 110 in the region of the openings 121, so that a respective local Aluminum rear side field (BSF, Back Surface Field) is generated at these points. This configuration of an Aluminum-Silicon contact favours to suppress the recombination of the generated charge carriers. A solar cell 101, 100 produced with this construction can also be referred to as PERC-solar cell (Passivated Emitter and Rear solar Cell).

After firing the contact, the output solar cell 101 produced according to the above described process sequence, can be halved or divided into two solar cells 100 (cf. the FIGS. 5, 6, 21) as described above. For this purpose, the output solar cell 101 can be scratched on the rear side and subsequently mechanically broken by means of a Laser.

Subsequent to providing the solar cells 100, the further assembly of the photovoltaic module 200 is carried out. Here, a layout of solar cells 100 is made, which are interconnected via an electrical connecting structure. This takes place according to a predefined interconnection pattern.

By means of the following figures, aspects and details for interconnecting the solar cells 100 of the photovoltaic module 200 are explained in more details. The solar cells 100 can have a rectangular lateral contour, as it is also illustrated in the figures, or alternatively a pseudo-rectangular lateral contour. The following description applies for the rectangular as well as for pseudo-rectangular solar cells 100 shown.

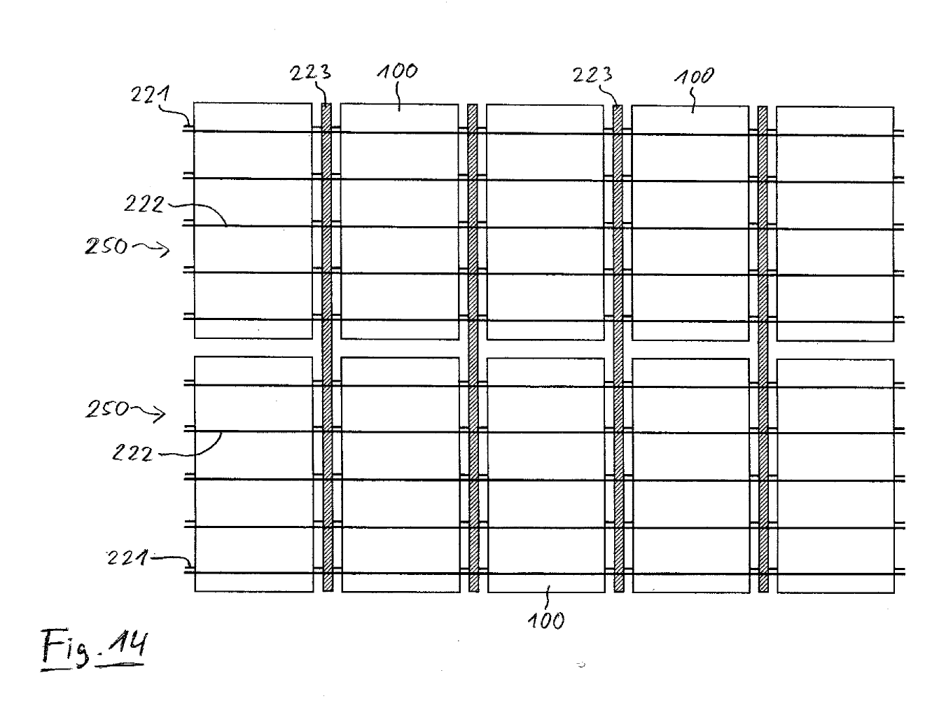

A possible configuration for a layout and interconnection of the solar cells 100 of the photovoltaic module 200 is shown in FIG. 11. The solar cells 100 are disposed in a plane in the form of a matrix in rows and columns. The matrix shown here exemplarily includes one hundred twenty solar cells 100. Several solar cells 100 are electrically connected in rows to a string 250 respectively. There are six such strings 250 formed, each of twenty half-cells 100, which are adjacently disposed and extend parallel to each other (in FIG. 11 in horizontal direction). In the individual strings 250, the solar cells 100 are respectively disposed with their long sides opposite each other. In FIG. 11, the series connections in the strings 250 are indicated by means of dashed lines or arrows. Here, wire guides 221, 222 are used as thin cell connectors (cf. the FIGS. 14, 15 and 20).

The shape of the solar cells 100 with the aspect ratio of 2:1 makes it possible that the string 250 can respectively include the double cell numbers than a comparable string of undivided or quadratic or pseudo-quadratic cells. Consequently, the double electric voltage can be generated by means of the string 250. However, the electric current flowing in the string 250 is smaller or halved. In this way, the operation of the photovoltaic module 200 is associated with low(er) ohmic resistive losses.

It is shown in FIG. 11 that respectively two adjacently disposed strings 250 are connected in parallel, whereby there are overall three string layouts 251, 252, 253 of parallel connected strings 250 (double-strings). By the parallel connection of respectively two strings 250, it can be achieved that the string layout 251, 252, 253 generate respectively the same voltage, in spite of the greater or double number of solar cells 100 per string 250 as a string made of undivided square cells. The string layouts 251, 252, 253—for their part—are interconnected in series. The parallel connection of the strings 250 and the series connection of the string layouts 251, 252, 253 is made by means of cross-connectors 241, 242, 243, 244, which are disposed at the ends of the strings 250 or on two opposite sides of the solar cell matrix. The electrical connection between the cross-connectors 241, 242, 243, 244 and the solar cells 100 present at these points is likewise realized by means of wire guides 221, 222.

A current path present in the interconnection pattern of FIG. 11 extends between the cross-connectors 241, 244, and has an (inverse) S-shape. Starting from the cross connectors 241, the electrical connection extends via the string layout 251, the cross connector 242, the string layout 252, the cross connector 243 and the string layout 253 to the cross connector 244 (or vice versa as well).

The layout of FIG. 11 can further be designed such that in the individual string layouts 251, 252, 253, the respective adjacently disposed solar cells 100 of the two different strings 250 (i.e. the solar cells 100 disposed adjacently in vertical direction in FIG. 11) are additionally connected one below the other. This can be realized by means of intermediate connectors 223 disposed between the solar cells 100 in the string layouts 251, 252, 253, which are connected to wire guides 221, 222 of the associated two strings 250 (cf. the FIGS. 14, 15).

The additional cell by cell parallel connection of solar cells 100 in the string layouts 251, 252, 253 enables the flow of the equalization currents between the solar cells 100 connected in parallel one below the other. In this way, for example, power losses resulting from partial shadowing can be reduced. This relates to direct shadowing of the solar cells 100 in the region of the front side as well as shadowing in the surroundings of the photovoltaic module 200, which leads to a reduction of the scattered light that can be collected over the rear side of the bifacial solar cells 100.

The cell by cell parallel connection can also be proved to be advantageous in view of the above described parts of output solar cells 101. Because, an output solar cell 101 can be divided, if necessary, into two solar cells 100 with different cell characteristics and so, levels of efficiency. To avoid the power losses associated herewith, it is proposed that the adjacently disposed and additionally connected in parallel one below the other solar cells 100 in the string layouts 251, 252, 253 (according to FIG. 11 vertical) respectively result from the same output solar cell 101. Different cell characteristics (if available) can be compensated by the possible flow of the equalization currents.

In the photovoltaic module 200, the electric connection of the solar cells 100 in the strings 250 occurs by means of wire guides 221, 222. Details for a construction to be considered, in which additional intermediate connectors 223 are used, are described in the following by means of possible manufacture of a string layout or a double-string made of two strings 250 shown in the FIGS. 11 to 15. Here, it can involve one of the string layouts 251, 252, 253 of FIG. 11.

At the start of the process sequence, as shown in FIG. 12, several wire guides 221 are provided. For this purpose, the wire guides 221 can be unrolled from the coils, not shown. The wire guides 221, which are provided for connection to the contact surfaces 173 of the rear side contact grid 170 of the solar cells 100 (cf. FIG. 3; same applies in pseudo-rectangular solar cells 100), are also referred to in the following as first wire guides 221. The first wire guides 221 are disposed extending parallel to each other, so that a corresponding wire field of first wire guides 221 is made. The number of the wire guides 221 is adapted to the number of the contact surfaces 173 per contact element 171 of the solar cells 100. With reference to the above described configuration of the solar cells 100 and the two strings 250 to be generated, the wire field shown in FIG. 12 includes ten first wire guides 221.

Then, as represented in FIG. 13, solar cells 100 and intermediate connector 223 are disposed on the first wire guides 221. The solar cells 100 are laid with the rear side on the first wire guides 221. The positioning of the solar cells 100 takes place such that in the strings 250 to be generated, the solar cells 100 face with their long sides, and that the contact surfaces 173 of the contact grid 170 of the solar cells 100 are touching in the region of the wire guides 221 (cf. the FIGS. 3, 4; same applies in pseudo-rectangular solar cells 100).

The intermediate connectors 223 are disposed in the gaps between the solar cells 100 on the first wire guides 221 and extend here perpendicular to the wire guides 221, as shown in FIG. 13. The intermediate connectors 223 have such a length that the intermediate connectors 223 extend between the solar cells 100 of the two strings 250 to be generated, and so the intermediate connectors 223 can be connected to the wire guides 221 (and also subsequently used wire guides 222) of the different strings 250. In this way, the above explained cell by cell parallel connection of solar cells 100 can be realized in a double-string.

The intermediate connectors 223, as is indicated in FIG. 13, can be strips or beam-like elements. The intermediate connectors 223 can have a thickness corresponding to the thickness of the solar cells 100, whereby it is possible to avoid the pressure being exerted on cell edges, after completing the strings 250. Furthermore, the intermediate connectors 223 can also be configured in the form of wire shaped elements or wire guides.

Subsequently, as is shown in FIG. 14, a layout or a wire field made of wire guides 222—broader and extending parallel to each other—can be positioned on the solar cells 100 (or their front sides). Even the wire guides 222 can be unrolled from the coils, not shown. The wire guides 222 (cf. FIG. 2; same applies in pseudo-rectangular solar cells 100) provided for connecting the contact surfaces 153 of the front side contact grids 150 of the solar cells 100 are also referred to as second wire guides 222 in the following. In a corresponding thickness of the intermediate connectors 223, the second wire guides 222 are also located on the intermediate connectors 223. The number of the second wire guides 222 corresponds to the front side contact surface number of the solar cells 100 and the two strings 250 to be generated. In view of the above described configuration of the solar cells 100, the wire field shown in FIG. 14 includes ten second wire guides 222. The layout of the second wire guides 222 takes place such that the wire guides 222 are located in the region of the contact surfaces 153 of the solar cells 100 (cf. the FIGS. 2, 4; same applies in pseudo-rectangular solar cells 100).

In FIG. 14, the wire field of second wire guides 222 is represented offset with respect to the wire field of first wire guides 221, for reasons of the clarity. Such an offset layout, for example, which is can be preferred by a configuration of the solar cells 100 according to FIG. 4, can also be realized in practice. Alternatively, a layout of the second wire guide 222 congruent to the first wire guides 221 is also possible.

From this point onwards, a soldering process is carried out, in which the contact surfaces 173 of the rear side contact grids 170 of the solar cells 100 and the first wire guides 221, the contact surfaces 153 of the front side contact grids 150 of the solar cells 100 and the second wire guides 222, as well as the intermediate connectors 223 and the wire guides 221, 222 are electrically interconnected. In the soldering process, corresponding solder joints can be configured successively or also simultaneously.

In view of the soldering process, wire guides 221, 222 are provided with a coating of the solder 232 for the process carried out before. For illustration, a corresponding sectional representation of a possible structure of the wire guides 221, 222 is shown in FIG. 16. The wire guides 221, 222 have a wire or base wire 231, for example, of copper, which is coated with the solder 232.

After making the electrical contacts or solder joints between the wire guides 221, 222 and the solar cells 100 and the wire guides 221, 222 and the intermediate connectors 223, the front and rear side of the solar cells 100 disposed in both the strings 250 are still short-circuited via the wire guides 221, 222 in the state illustrated in FIG. 14. Therefore, as represented in FIG. 15, surplus electric connections are interrupted in order to realize a series connection. Here, the wire guides 221, 222 are severed at suitable points 229. The severing points 229 can be configured, for example, by means of a Laser or also mechanically by means of a slitting device.

After isolating the short circuit connections, the solar cells 100 of a string 250 are electrically connected in series. The serial connection between adjacent solar cells 100 of a string 250 is made respectively via several (presently five) wire guides 221, which are disposed on the rear side and are connected to the contact grid 170 of one of the solar cells 100, one intermediate connector 223 and several (presently five) wire guides 222, which are disposed on the front side and are connected to the contact grid 150 of a solar cells 100 adjacent thereto. By means of the intermediate connectors 223, to which wire guides 221, 222 of the two different string 250 are connected, furthermore the cell by cell parallel connection of adjacently disposed solar cells 100 of the different strings 250 is made.

The above described process sequence offers the possibility of electrically interconnecting solar cells 100 of the photovoltaic module 200 in a cost-effective and reliable manner. The use of the wire guides 221, 222 also favours a low front and rear side shadowing of the solar cells 100.

In this context, it is further possible to use the described process sequence for realizing a predefined interconnection pattern, for example, the pattern of FIG. 11. Here, initially a layout with all strings 250 or string layouts to be made corresponding to FIG. 14 can be provided. For this purpose, wire fields with a corresponding (or greater) number of wire guides 221, 222 are used. Even cross connectors, such as the cross connectors 241, 242, 243, 244 shown in FIG. 11 can be taken into consideration, in which the cross connectors 241, 242, 243, 244 can be provided between the wire guides 221, 222 additionally on the side of the solar cells matrix, comparable to the solar cells 100 and intermediate connectors 223. In the subsequent soldering process, solder joints between the wire guides 221, 222 and the solar cells 100 and the wire guides 221, 222 and the intermediate connectors 223 within the string 250, and also between the wire guides 221, 222 and the cross connectors 241, 242, 243, 244 at the ends of the string 250 can be made. In the following isolation step, besides short circuit connections within the string 250, even connections on the side of the solar cells matrix can be interrupted, so that the cross connectors 241, 242, 243, 244 are electrically connected with the solar cells 100 adjacent thereto, only via the wire guides 221 or the wire guides 222.

After interconnecting the solar cells 100 or making the electrical connecting structure, the further steps explained above are taken, in order to complete the photovoltaic module 200. This includes embedding the electrically connected solar cells 100 in the embedding layer 214 between the covers 211, 212 and if necessary, carried out the attachment of the frame 216 (cf. FIG. 1).

In the following, further possible configurations are described, which can be considered for the photovoltaic module 200. In this context, it should be noted that same and similarly working components and structures will not be described again in the following. For detail thereof, instead a reference is made to the above description. A reference is also made to the possibility of combining the features of different configurations with each other.

For example, it is possible to modify the process sequence explained by means of the FIGS. 12 to 15 such that solar cells 100 are first laid with their front sides on a wire field, and subsequently another wire field is positioned at the rear side on the solar cells 100, before the further steps (soldering process, isolation of surplus connection) are carried out.

With reference to the electrical connecting structure, furthermore, a configuration with one or more electric bridge structures can be provided, in order to prevent—in case of a malfunction, such as a partial shadowing—a negative impairment of the current flow in the photovoltaic module 200. For illustrating such a construction, FIG. 17 shows another interconnection pattern, which can be provided for the photovoltaic module 200. The construction of FIG. 17, which is based on the construction of FIG. 11, includes additional bridge structures. Here, two bridge connectors 261, 262 extending parallel to the string layouts 251, 252, 253 are used, which are connected to the cross connectors 241, 242, 243, 244 disposed on the side of the solar cells matrix. The bridge connector 261 is connected on the side with the cross connectors 242 and to the opposite side via bypass-diodes 270 with the cross-connectors 241, 243. The other bridge connector 262 is connected to a side with the cross connector 243 and to the opposite side via a bypass-diode 270 with the cross connector 244.

The interconnection shown in FIG. 17 offers the possibility to bridge a string layout 251, 252, 253 in case of a malfunction. This is done by responding or switching a corresponding bypass-diode 270, whereby the electric current can be bypassed via the bridge connectors 261, 262 connected to the bypass-diode 270. Two or all three string layouts 251, 252, 253 can also be bridged.

It is possible with reference to the construction of FIG. 17, to arrange the solar cells 100 along with the bridge connectors 261, 262, the bypass-diodes 270 and the remaining components of the electrical connecting structure (such as the wire guides 221, 222) to each other, to connect these components in a soldering process, to isolate the short circuit connections, and subsequently to arrange in the embedding layer 214 between the covers 211, 212. Alternatively, it can be conceived to omit the bypass-diodes 270 in these processes, and to install the bypass-diodes 270 only later or after the lamination according to the interconnection pattern of FIG. 17. Here, the bypass-diodes 270 are accommodated, for example, in the junction boxes (not represented) provided on the photovoltaic module 200.

The connection of solar cells 100 of the photovoltaic module 200 by means of wire guides 221, 222 cannot be realized only with the process sequence of the FIGS. 12 to 15, but in other ways as well. A possible variant will be described in the following by means of making an individual solar cell string 250 shown in the FIGS. 18 to 20.

In this process sequence, top view shown in FIG. 18 and layout of solar cells 100 and first and second wire guides 221, 222 shown from the side in FIG. 19 is provided. The solar cells 100 with their long sides face each other. A wire field of parallel first wire guides 221 extends alternating on the front and rear side of the solar cells 100. A wire field of parallel second wire guides 222 extends vice-versa thereto, alternating on the front and rear side of the solar cells 100. In both wire fields, the wire guides 221, 222 are provided for connection to the front as well as to the rear side contact grids 150, 170 of the solar cells 100. In the sides of the solar cells 100 shown in FIG. 18 (and also 20) in the top view, can include their front sides.

The number of the wire guides 221, 222 corresponds to the contact surface number of the solar cells 100, so that in view of the string 250 and the above described configuration of the solar cells 100, five first wire guides 221 and five second wire guides 222 are represented in FIG. 18. The wire guides 221, 222 are positioned such that the wire guides 221, 222 are located in the region of the front and rear side contact surfaces 153, 173 of the solar cells 100 (cf. the FIGS. 2, 3, 4; same applies to pseudo-rectangular solar cells 100).

The wire fields of the first and second wire guides 221, 222 are offset laterally (according to FIG. 18 in vertical direction) with respect to each other, so that the wire guides 221, 222 are spaced apart from each other in the gaps between the solar cells 100. Such a layout can be favoured by the configuration of the solar cells 100 shown in FIG. 4.

The web-like structure shown in the FIGS. 18, 19 can be realized, in which solar cells 100 are sequentially positioned between the wire fields of first and second wire guides 221, 222, and the wire guides 221, 221 can be disposed reversed with respect to the front and rear side of the solar cells 100 before the positioning of the respective next solar cell 100.

After making the layout shown in the FIGS. 18, 19, a soldering process is carried out, in which the first and second wire guides 221, 222 are connected to the solar cells. The connection is made according to the layout of the wire guides 221, 222 on the front or rear side of the solar cells 100, on the front or rear side contact surfaces 153, 173 of the contact grids 150, 170 of the solar cells 100.

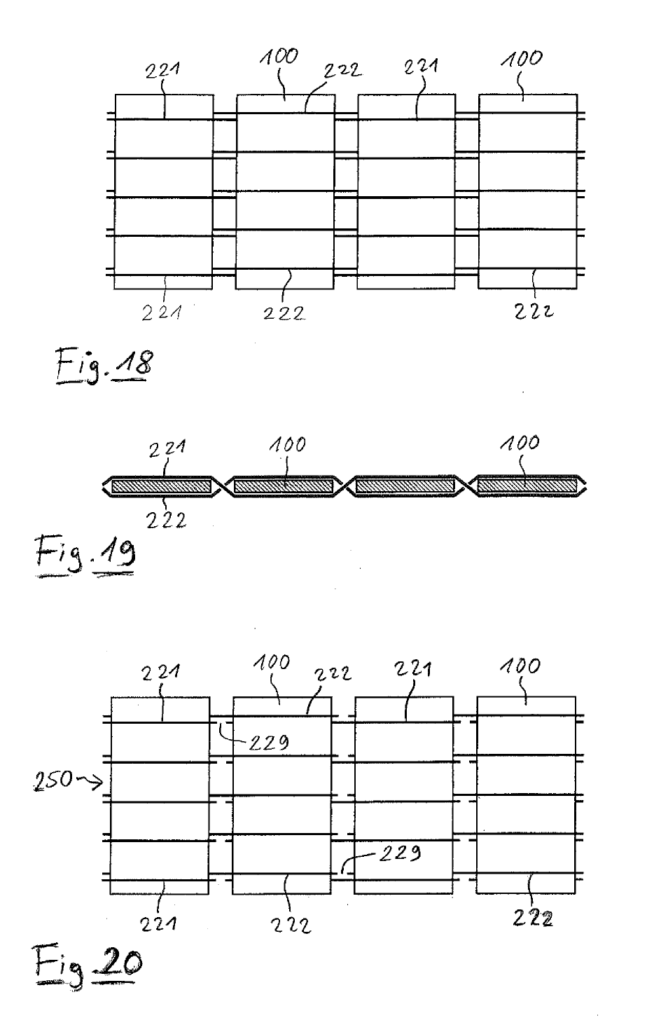

After making the solder joints between the wire guides 221, 222 and the solar cells 100, in the state illustrated in FIG. 18, there is still a short circuit connection. Therefore, as it is represented in FIG. 20, surplus electrical connections are interrupted, in which the wire guides 221, 222 are severed at suitable points 229. In this way, the solar cells 100 of the strings 250 are electrically connected in series. Between adjacent solar cells 100, the serial connection is made alternating either respectively via several (presently five) severed first wire guides 221 or several (presently five) severed second wire guides 222, which are connected to the front and rear side contact grids 150, 170 of the relevant solar cells 100.

In view of the realization of a predefined interconnection pattern, for example the pattern of FIG. 11, initially a layout corresponding to the FIGS. 18, 19 with all strings 250 or string layouts to be generated can be provided. Even cross connectors 241, 242, 243, 244, as shown in FIG. 11, can be taken into consideration, in which additionally on the side of the solar cells matrix, comparable to the solar cells 100, the cross connectors 241, 242, 243, 244 are provided between the wire guides 221, 222. In the subsequent soldering process, solder joint can be made between the wire guides 221, 223 and the contact grids 150, 170 of the solar cells 100 within the strings 250, and also between the wire guides 221, 222 and the cross connectors 241, 242, 243, 244. In the subsequent isolation step, besides surplus connections within the strings 250, connections on the side of the solar cells matrix can also be interrupted, so that the cross connectors 241, 242, 243, 244 are electrically connected to the solar cells 100 adjacent thereto, only via the wire guides 221 or the wire guides 222.

As was explained above, the photovoltaic module 200 can be realized not only with rectangular, but also with pseudo-rectangular solar cells 100. For this purpose, pseudo-quadratic output solar cells 101 can be produced according to the process sequence of the FIGS. 7 to 10 and can be halved in two respective pseudo-rectangular solar cells 100. For illustrating this procedure, such a pseudo-quadratic output solar cell 101 or its contour is represented in FIG. 21. The division of the output solar cell 101 into two half-cells 100 is indicated by means of arrows and a dashed line. The pseudo-quadratic output solar cell 101 has a shape corresponding to a square with four chamfered corner areas. The configuration with such a lateral shape can be selected, for example, based on a Czochralski or Float-zone process carried out during the manufacture and generating a circular cylindrical Silicon rod associated hereto.

Apart from the different contour, the pseudo-quadratic output solar cell 101 has the same construction as a square output solar cell 101, i.e. for example, the contact grids 150 and 170 on the front and rear side, which in view of the two half-cells 100 formed by the isolation step, include the double number of contact elements 151, 171. In this configuration also, the division occurs in the middle of the output solar cell 101 between two contact elements 151 or 171 (each not represented in FIG. 21, cf. the usable FIGS. 5, 6 analogous hereto).

A pseudo-rectangular solar cell 100 or its contour formed by dividing the pseudo-quadratic output cell 101 is shown in FIG. 22. The shape of the solar cell 100 corresponds to a rectangular basic shape indicated in FIG. 22 by means of dashed lines, wherein two corner areas are chamfered, deviating from the rectangular basic shape. In this configuration, the solar cell 100 has two long sides with different lengths and two short sides, which are shorter than the corresponding short sides of the rectangular basic shape. Based on the division of the underlying pseudo-quadratic output solar cell 101, the pseudo-rectangular solar cell 100 also has an aspect ratio of 2:1. Here, this refers to the long and short sides of the rectangular basic shape.

The embodiments explained by means of the figures represent preferred or exemplary embodiments of the invention. Besides the described and depicted embodiments, further embodiments can be conceived, which can include further modifications and/or combinations of features.

For example, it is possible to use other materials instead of the above specified materials. The same applies for the numerical data and the number of components and elements shown in the figures, which can be replaced by other data and numbers. In this respect, it is possible, for example, to configure a solar cells matrix, which includes different numbers of solar cells, strings, string layouts and/or parallel connected strings per string layout. Furthermore, solar cells with different numbers of contact elements and different numbers of contact surfaces per contact element can be used.

In addition, solar cells with a construction deviating from one of the above described ones can be made and used. Further, solar cells with a different aspect ratio can be employed, for example with an aspect ratio of 3:1. Such solar cells can likewise be made by dividing the square or pseudo-quadratic output solar cells.

With reference to pseudo-quadratic and pseudo-rectangular solar cells, further configurations are possible, which have—instead of chamfered corner area—round or rounded corner areas or even corner areas with chamfered and rounded partial areas. Further, such solar cells can have a different number of chamfered and/or rounded corner areas. The number of chamfered and/or rounded corner areas can be between one and four.

1. Bifacial solar cell, comprising a first contact grid with first contact elements on a first side and a second contact grid with second contact elements on a second side opposite to the first side,
wherein the first and second contact elements have several sections, which are configured alternating in the shape of contact lines and contact surfaces,
wherein the second side has a passivation layer with openings,
wherein the second contact elements extend at least partially into the openings of the passivation layer,
and wherein the first and second contact elements are configured such that the contact surfaces of different first contact elements and the contact surfaces of different second contact elements are respectively disposed in several rows.

2. Solar cell according to claim 1, wherein the first and second contact elements are configured such that the contact surfaces of different first contact elements and the contact surfaces of different second contact elements are respectively disposed in five rows.

3. Solar cell according to claim 2, wherein the solar cell has a substrate of Silicon with a p-doped base and an n-doped emitter,
and wherein the contact lines of the second contact elements have Aluminum.

4. Photovoltaic module comprising several solar cells according to claim 2 and an electrical connecting structure, through which the solar cells are electrically connected, wherein the electrical connecting structure has cell connectors connected to the first and second contact elements of the solar cells.

5. Photovoltaic module according to claim 4, wherein five cell connectors are respectively connected to the first and second contact elements of the solar cells.

6. Photovoltaic module according to claim 4, wherein the cell connectors are connected to the first and second contact elements of the solar cells via a solder joint.

7. Photovoltaic module according to claim 4, wherein the solar cells are configured rectangular with an aspect ratio different from one, particularly with an aspect ratio of 2:1.

8. Photovoltaic module according to claim 7, wherein the solar cells are connected via the electrical connecting structure such that the photovoltaic module has several strings of solar cells connected in series, wherein in the strings, the solar cells are disposed with their long side opposite each other, and wherein several strings are connected in parallel.

9. Photovoltaic module comprising several solar cells and an electrical connecting structure through which the solar cells are electrically connected,
wherein the solar cells are configured rectangular with an aspect ratio different from one,
wherein the solar cells have a first contact grid with first contact elements on a first side and a second contact grid with second contact elements on the second side opposite to the first side,
and wherein the electrical connecting structure has wire guides connected to the first and second contact elements of the solar cells.

10. Photovoltaic module according to claim 9, wherein the first and second contact elements of the solar cells have several sections, which are configured alternating in the shape of contact lines and contact surfaces, and wherein the wire guides are connected to the contact surfaces of the first and second contact elements.

11. Photovoltaic module according to claim 10, wherein the contact lines of the first or second contact elements of the solar cells have Aluminum.

12. Photovoltaic module according to claim 11, wherein at least five wire guides are connected to the first and second contact elements of the solar cells.

13. Photovoltaic module according to claim 12, wherein the wire guides are connected to the first and second contact elements of the solar cells via a solder joint.

14. Photovoltaic module according to claim 13, wherein the solar cells have an aspect ratio of 2:1.

15. Photovoltaic module according to claim 14, wherein the solar cells comprise a substrate of Silicon with a p-doped base and an n-doped emitter.
